(19) United States
(12) Patent Application Publication
(10) Pub. No.: US 2011/0183463 A1
(43) Pub. Date: Jul. 28, 2011

(54) THIN FILM TRANSITOR SUBSTRATE AND METHOD OF MANUFACTURING THE SAME

(75) Inventors: Sung-Ryul KIM, Cheonan-si (KR); Sung-Hoon YANG, Seoul (KR); Byoung-June KIM, Seoul (KR); Czang-Ho LEE, Suwon-si (KR); Jae-Ho CHOI, Seoul (KR); Hwa-Yeul OH, Suwon-si (KR); Yong-Mo CHOI, Suwon-si (KR)

(73) Assignee: SAMSUNG ELECTRONICS CO., LTD., Suwon-si (KR)

(21) Appl. No.: 12/961,170

(22) Filed: Dec. 6, 2010

Related U.S. Application Data
(62) Division of application No. 12/100,436, filed on Apr. 10, 2008, now abandoned.

(30) Foreign Application Priority Data
Apr. 18, 2007 (KR) 10-2007-0037800

(51) Int. Cl. H01L 21/336

(52) U.S. Cl. 438/104; 257/E21.411

(57) ABSTRACT

A method of manufacturing a thin film transistor (“TFT”) substrate includes forming a first conductive pattern group including a gate electrode on a substrate, forming a gate insulating layer on the first conductive pattern group, forming a semiconductor layer and an ohmic contact layer on the gate insulating layer by patterning an amorphous silicon layer and an oxide semiconductor layer, forming a second conductive pattern group including a source electrode and a drain electrode on the ohmic contact layer by patterning a data metal layer, forming a protection layer including a contact hole on the second conductive pattern group, and forming a pixel electrode on the contact hole of the protection layer. The TFT substrate including the ohmic contact layer formed of an oxide semiconductor is further provided.

This application is a divisional of U.S. application Ser. No. 12/100,436, filed on Apr. 10, 2008, which claims priority to Korean Patent Application No. 10-2007-0037800, filed on Apr. 18, 2007, and all the benefits accruing therefrom under 35 U.S.C. §119, the contents of which in its entirety are herein incorporated by reference.

### BACKGROUND OF THE INVENTION

1. Field of the Invention

The present invention relates to a thin film transistor (“TFT”) substrate and a method of manufacturing the same, and more particularly, to a TFT substrate having an ohmic contact layer and a method of manufacturing the TFT substrate including forming the ohmic contact layer.

2. Description of the Related Art

Liquid crystal display (“LCD”) devices display images by controlling a light transmission ratio of liquid crystal by an electric field. An LCD device includes a liquid crystal panel with liquid crystal cells arranged in a matrix and a driving circuit for driving liquid crystal. Herein, the liquid crystal panel includes the TFT substrate with a TFT array formed, a color filter substrate with a color filter array formed, and liquid crystal interposed between the two substrates.

The liquid crystal panel includes a liquid crystal cell positioned at an area intersected between a gate line and a data line. Each of the liquid crystal cells includes a pixel electrode receiving an image data signal and a common electrode receiving a common voltage. The liquid crystal cell includes a TFT connected with the gate line, the data line, and the pixel electrode and displays images by supplying the pixel electrode with an image data signal supplied to the data line when a scan signal is supplied to the gate line.

Recently, an inverted staggered structure of a bottom gate which can relatively be formed easily without a light blocking layer is most widely used as a method of manufacturing the TFT substrate. A method of manufacturing the TFT of the inverted staggered structure includes a back channel etched (“BCE”) method for simplifying a fabrication process and an etch stopper (“ES”) method for improving a property of the TFT according to a process of forming a channel.

Since the BCE method performs an etching process of an ohmic contact layer after forming a data pattern, it can reduce the number of masks and continuously form a gate insulating layer and a semiconductor layer, and the ohmic contact layer within the same chamber.

### BRIEF SUMMARY OF THE INVENTION

It has been determined herein, according to the present invention, that since the BCE method should perform over-etching for completely removing the ohmic contact layer in a channel portion, it should occupy a margin by thickly forming the semiconductor layer. Therefore, the BCE method increases a process time, a leakage current, and a serial contact resistance, thereby degrading a property of the TFT such as a reduction of an electron mobility, etc.

It has also been determined herein, according to the present invention, that since the ES method can thinly form the semiconductor layer but should pattern the etch stopper, it has a drawback of adding a mask process.

Accordingly, the present invention provides a TFT substrate and a method of manufacturing the same capable of simplifying a fabrication process and improving a property of a TFT by forming an ohmic contact layer with an oxide semiconductor.

A method of manufacturing a TFT substrate according to the present invention includes forming a first conductive pattern group including a gate electrode on a substrate, forming a gate insulating layer on the first conductive pattern group, forming a semiconductor layer and an ohmic contact layer on the gate insulating layer by patterning an amorphous silicon layer and an oxide semiconductor layer, respectively, forming a second conductive pattern group including a source electrode and a drain electrode on the ohmic contact layer by patterning a data metal layer, forming a protection layer including a contact hole on the second conductive pattern group, and forming a pixel electrode electrically connected to a portion of the drain electrode through the contact hole on the protection layer.

In forming the second conductive pattern group, the data metal layer and the ohmic contact layer may simultaneously be patterned by a wet etching.

Forming the ohmic contact layer may include patterning the oxide semiconductor layer formed of zinc oxide, and may include adding any one of elements of group I, group III, group V, and group VII in the periodic table to the zinc oxide.

Alternatively, the ohmic contact layer may include patterning the oxide semiconductor layer formed of indium oxide, indium tin oxide, indium zinc oxide, or an amorphous oxide semiconductor.

In other exemplary embodiments of the present invention, a method of manufacturing a TFT substrate includes forming a first conductive pattern group including a gate electrode on a substrate, depositing a gate insulating layer, an amorphous silicon layer, an oxide semiconductor layer, and a data metal layer on the first conductive pattern group, forming a second conductive pattern group including a semiconductor layer, an ohmic contact layer, a source electrode, and a drain electrode by patterning the amorphous silicon layer, the oxide semiconductor layer, and the data metal layer, respectively, forming a protection layer including a contact hole on the second conductive pattern group, and forming a pixel electrode electrically connected to a portion part of the drain electrode through the contact hole on the protection layer.

In forming the second conductive pattern group, the data metal layer and the ohmic contact layer can simultaneously be patterned by a wet etching.

Forming the ohmic contact layer may include patterning the oxide semiconductor layer formed of zinc oxide, and may further include adding any one of elements of group I, group III, group V, and group VII in the periodic table to the zinc oxide.

Forming the ohmic contact layer may include patterning the oxide semiconductor layer formed of indium oxide, indium tin oxide, indium zinc oxide, or an amorphous oxide semiconductor.

In still other exemplary embodiments of the present invention, a TFT substrate includes a gate electrode formed on a substrate, a gate insulating layer formed to cover the gate electrode, a semiconductor layer formed to overlap the gate electrode on the gate insulating layer, an ohmic contact layer formed of an oxide semiconductor on the semiconductor layer, and a source electrode and a drain electrode formed on the ohmic contact layer.

The TFT substrate may further include a protection layer formed on the source electrode and the drain electrode and having a contact hole, and a pixel electrode formed on the protection layer and connected to a portion of the drain electrode through the contact hole.

The ohmic contact layer may be formed of zinc oxide, and may be formed by adding any one of elements of group I, group III, group V, and group VII in the periodic table to the zinc oxide.

The ohmic contact layer may be formed of indium oxide, indium tin oxide, indium zinc oxide, or an amorphous oxide semiconductor.

### BRIEF DESCRIPTION OF THE DRAWINGS

The above and other features of the present invention will be described in reference to certain exemplary embodiments thereof with reference to the attached drawings in which:

FIG. 1 is a plan view showing an exemplary embodiment of a TFT substrate in accordance with the present invention;

FIG. 2 is a cross-sectional view showing the exemplary TFT substrate taken along line I-I′ of FIG. 1;

FIGS. 3A to 3E are cross-sectional views sequentially showing a first exemplary embodiment of a method of manufacturing the exemplary TFT substrate in accordance with the present invention; and

FIGS. 4A to 4E are cross-sectional views sequentially showing a second exemplary embodiment of a method of manufacturing the exemplary TFT substrate in accordance with the present invention.

### DETAILED DESCRIPTION OF THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “lower”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “lower” other elements or features would then be oriented “upper” the other elements or features. Thus, the exemplary term “lower” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

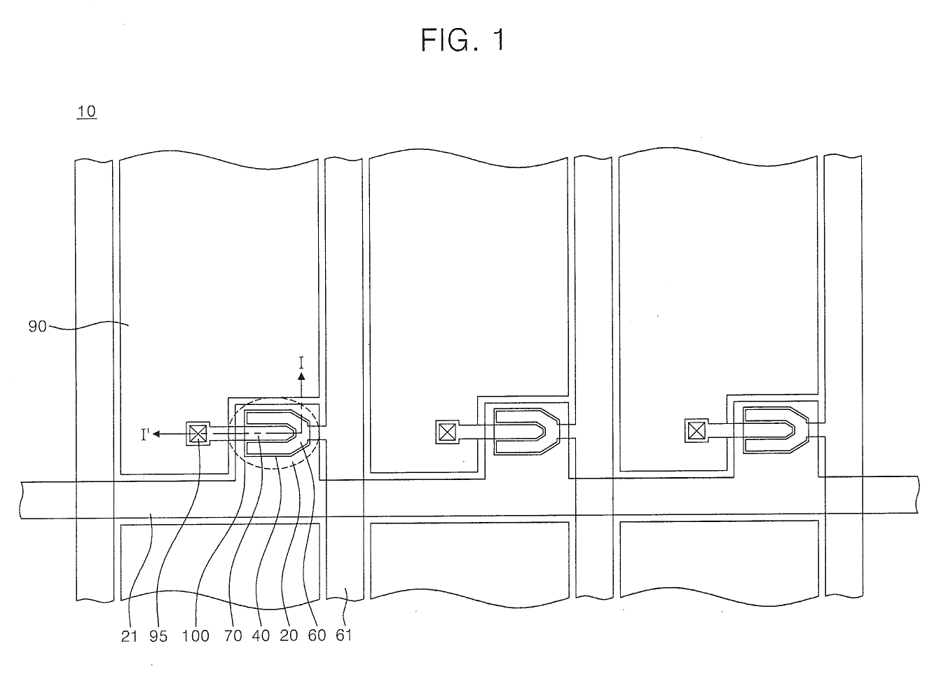

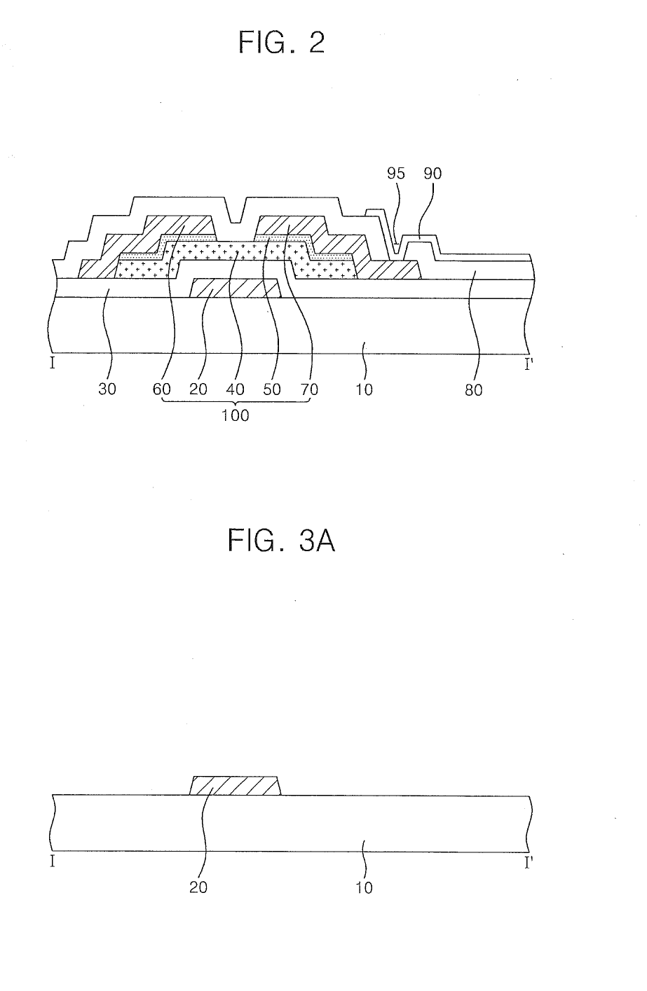

FIG. 1 is a plan view showing an exemplary embodiment of a thin film transistor (“TFT”) substrate in accordance with the present invention and FIG. 2 is a cross-sectional view showing the exemplary TFT substrate taken along line I-I′ of FIG. 1.

Referring to FIGS. 1 and 2, the exemplary embodiment of the TFT substrate according to the present invention includes a substrate 10, a gate line 21, a data line 61, a pixel electrode 90, and a TFT 100.

The substrate 10 includes an insulating substrate where the gate line 21, the data line 61, the pixel electrode 90, and the TFT 100 are formed and is preferably formed of a material such as a transparent glass or a plastic.

The gate line 21 supplies the TFT 100 with a scan signal and the data line 61 supplies the TFT 100 with an image date signal. The gate line 21 extends substantially in a first direction, while the data line 61 extends substantially in a second direction perpendicular to the first direction. The gate line 21 and the data line 61 are formed to intersect on the substrate 10 with a gate insulating layer 30 interposed therebetween. A pixel area includes the TFT 100 connected to the gate line 21 and the data line 61 and the pixel electrode 90 connected to the TFT 100. A matrix of pixels may be provided on the substrate 10.

The TFT 100 supplies the image data signal supplied from the data line 61 to the pixel electrode 90 in response to the scan signal supplied from the gate line 21. For doing this, the TFT 100 includes a gate electrode 20, a source electrode 60, a drain electrode 70, a semiconductor layer 40, and an ohmic contact layer 50.

The gate electrode 20 is connected to the gate line 21, the source electrode 60 is connected to the data line 61, and the drain electrode 70 is connected to the pixel electrode 90. The gate electrode 20 may be formed within a same layer as the gate line 21 and may protrude from the gate line 21. The source electrode 60 and the drain electrode 70 may be formed within a same layer as the data line 61, and the source electrode 60 may protrude from the data line 61. The semiconductor layer 40 is formed to overlap the gate electrode 20 with the gate insulating layer 30 interposed therebetween. The semiconductor layer 40 forms a channel between the source and drain electrodes 60 and 70.

In an exemplary embodiment, the ohmic contact layer 50 is formed of an oxide semiconductor for ohmic-contact between the source and the drain electrodes 60 and 70 and the semiconductor layer 40. Since the oxide semiconductor is mainly an n-type material and its carrier concentration is higher than that of an amorphous silicon layer doped with impurity (“n+a-Si:H”), which constitutes a conventional ohmic contact layer, it may function as a good contact layer between the source and drain electrodes 60 and 70 made of a metal material and the semiconductor layer 40 made of an amorphous silicon (“a-Si”) material.

Additionally, the oxide semiconductor has an advantage in a fabrication process of the TFT substrate by enabling a wet etching process like the source and drain electrodes 60 and 70. An advantage in a fabrication process of the ohmic contact layer 50 with the oxide semiconductor will now be described in detail in a method of manufacturing the TFT substrate.

Meanwhile, in exemplary embodiments, the oxide semiconductor includes zinc oxide (ZnO) and zinc oxide (ZnO)-based material adding an additive. The additive may be any one of elements of group I, group III, group V, and group VII in the periodic table, and may be elements of group I including hydrogen (H), lithium (Li), sodium (Na), potassium (K), rubidium (Rb) and cesium (Cs), group III including scandium (Sc), yttrium (Y) and lanthanum (La), group V including vanadium (V), niobium (Nb), tantalum (Ta) and dubnium (Db) or group VII including manganese (Mn), technetium (Tc), rhenium (Re) and bohrium (Bh) in the periodic table.

In exemplary embodiments, the oxide semiconductor includes an amorphous oxide semiconductor such as indium oxide (In₂O₃), tin oxide (SnO₂), indium tin oxide ((In—Sn)Oₓ), indium zinc oxide ((In—Zn)Oₓ), etc.

The pixel electrode 90 is formed of a transparent conductive metal material such as indium tin oxide (“ITO”) or indium zinc oxide (“IZO”), etc. When the pixel electrode 90 receives the image data signal from the TFT 100, the pixel electrode 90 drives liquid crystal (not shown) along with a common electrode of a color filter substrate (not shown) receiving a common voltage, thereby controlling a light transmission ratio. The pixel electrode 90 is formed on a protection layer 80 covering the TFT 100 to expose the drain electrode 70 and is connected to the drain electrode 70 through a contact hole 95.

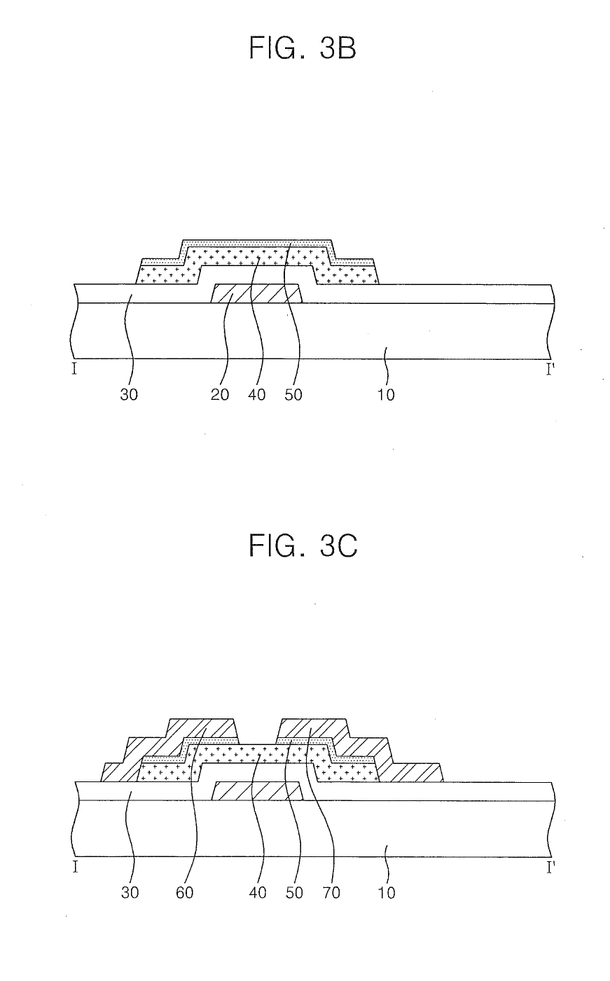

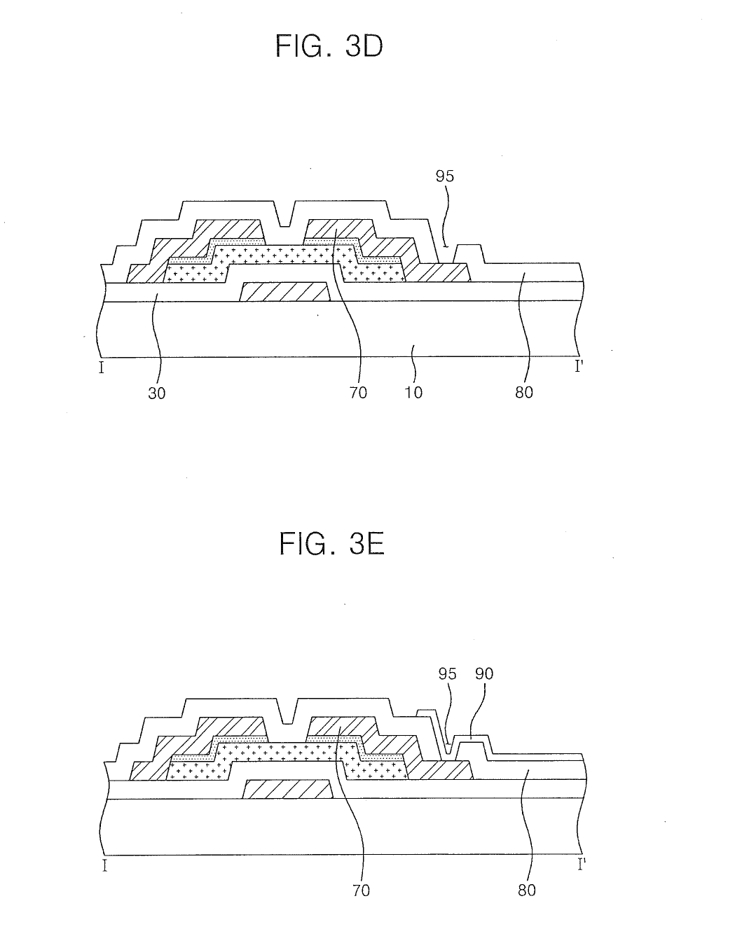

FIGS. 3A to 3E are cross-sectional views sequentially showing a first exemplary embodiment of a method of manufacturing an exemplary TFT substrate in accordance with the present invention, and cross-sectional views showing an exemplary method of manufacturing the exemplary TFT substrate using 5 masks.

First, FIG. 3A is a cross-sectional view showing the first exemplary embodiment of a first mask process in a method of manufacturing the exemplary TFT substrate in accordance with the present invention. The first mask process forms a first conductive pattern group on the substrate 10 using a first mask. The first conductive pattern group includes the gate line 21 (shown in FIG. 1) and the gate electrode 20.

A gate metal layer (not shown) is formed on the substrate 10 by a deposition method such as a sputtering. The gate metal layer may be formed of a single layer of a metal such as aluminum (Al), chromium (Cr), copper (Cu), and molybdenum (Mo), etc. or their alloy, or a multiple layer of their combination. Next, the gate metal layer is patterned by a photolithography process and an etching process using the first mask. The gate metal layer forms the first conductive pattern group including the gate line 21 and the gate electrode 20. Although not shown, in an alternative exemplary embodiment, a storage line and storage electrode may also be formed from the gate metal layer.

FIG. 3B is a cross-sectional view showing the first exemplary embodiment of a second mask process in the method of manufacturing the exemplary TFT substrate in accordance with the present invention. The second mask process sequentially forms the gate insulating layer 30, the semiconductor layer 40, and the ohmic contact layer 50 on the substrate 10, including the first conductive pattern group already formed thereon, using a second mask.

The gate insulating layer 30 and an a-Si layer (not shown) are formed by a deposition method such as a plasma enhanced chemical vapor deposition (“PECVD”) method, etc. on the substrate 10, including the gate line 21 and the gate electrode 20 already formed thereon. The gate insulating layer 30 may be made of an inorganic insulating material such as silicon nitride (SiNₓ), silicon oxide (SiOₓ), etc. Then, the oxide semiconductor layer (not shown) is deposited by a sputtering method.

Next, the a-Si layer and the oxide semiconductor layer are patterning by a photolithography process and an etching process using the second mask to form the semiconductor layer 40 and the ohmic contact layer 50.

As described with respect to FIGS. 1 and 2, the oxide semiconductor includes zinc oxide (ZnO), zinc oxide (ZnO)-based material adding an additive, a crystal oxide semiconductor, or an amorphous oxide semiconductor.

FIG. 3C is a cross-sectional view showing the first exemplary embodiment of a third mask process in the method of manufacturing the exemplary TFT substrate in accordance with the present invention. The third mask process forms a second conductive pattern group on the substrate 10, including the semiconductor layer 40 and the ohmic contact layer 50 already formed thereon, using a third mask. The second conductive pattern group includes the data line 61 (shown in FIG. 1), the source electrode 60, and the drain electrode 70.

A data metal layer (not shown) is deposited by a deposition method such as a sputtering method, etc. on the gate insulating layer 30 and the ohmic contact layer 50. The data metal layer may be formed of a single layer of a metal such as aluminum (Al), chromium (Cr), copper (Cu), and molybdenum (Mo), etc. or their alloy, or a multiple layer of their combination.

The data metal layer is patterned to form the second conductive pattern group including the data line 61, the source electrode 60, and the drain electrode 70. In an exemplary embodiment, a method of patterning the data metal layer indicates a wet etching which may pattern the ohmic contact layer 50 formed of the oxide semiconductor at the same time.

In a conventional process, an etching of the data metal layer uses a wet etching method and an etching of the ohmic contact layer and the semiconductor layer uses a dry etching method. However, according to an exemplary embodiment of the present invention, when the ohmic contact layer 50 is formed of the oxide semiconductor, the ohmic contact layer 50 may be patterned by a wet etching method along with the data metal layer.

Meanwhile, in an exemplary embodiment, a wet etchant used in a wet etching method has a high etch selectivity. The etch selectivity indicates that a wet etchant etches the data metal layer forming the data line 61, the source electrode 60, and the drain electrode 70 and the oxide semiconductor forming the ohmic contact layer 50 but does not etch the semiconductor layer 40 forming an active layer.

According to an exemplary embodiment of the present invention, two etching processes including a wet etching for forming a source electrode and a drain electrode and a dry etching for etching an ohmic contact layer and a semiconductor layer may be substituted with one wet etching process.

Additionally, according to an exemplary embodiment of the present invention, since the oxide semiconductor for forming the ohmic contact layer 50 is etched by a wet etchant while the semiconductor layer 40 including an active layer is not etched, the thickness of the semiconductor layer 40 including the active layer may be thinly formed unlike a conventional back channel etched (“BCE”) method. As a result, according to an exemplary embodiment of the present invention, properties of the TFT 100, such as a reduction in a photo leakage current and an increase in an electron mobility, may be improved.

FIG. 3D is a cross-sectional view showing the first exemplary embodiment of a fourth mask process in the method of manufacturing the exemplary TFT substrate in accordance with the present invention. The fourth mask process forms the protection layer 80 including the contact hole 95 on the gate insulating layer 30, including the second conductive pattern group already formed thereon, using a fourth mask.

More specifically, the protection layer 80 is formed by a deposition method such as a PECVD, a spin coating, etc. on the substrate 10, already including the second conductive pattern group formed thereon. The contact hole 95 penetrating the protection layer 80 and exposing the drain electrode 70 is formed by a photolithography process and an etching process using a fourth mask. The protection layer 80 may include an inorganic insulating material, such as the material used for forming the gate insulating layer 30, or an organic insulating material.

FIG. 3E is a cross-sectional view showing the first exemplary embodiment of a fifth mask process in the method of manufacturing the exemplary TFT substrate in accordance with the present invention. The fifth mask process forms the pixel electrode 90 on the protection layer 80 using a fifth mask.

More specifically, the pixel electrode 90 is formed by forming a transparent conductive layer (not shown) on the protection layer 80 by a method such as a sputtering, etc. and then patterning the transparent conductive layer by a photolithography process and an etching process using the fifth mask. The transparent conductive layer includes a transparent conductive material such as indium tin oxide (“ITO”), indium zinc oxide (“IZO”), and tin oxide (“TO”), etc. The pixel electrode 90 is connected to the drain electrode 70 through the contact hole 95.

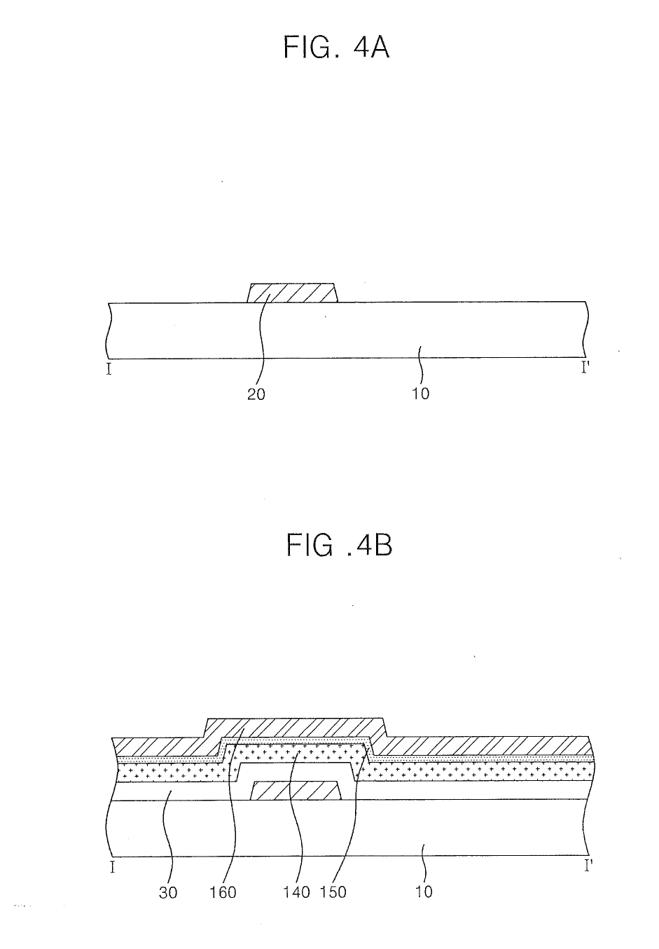

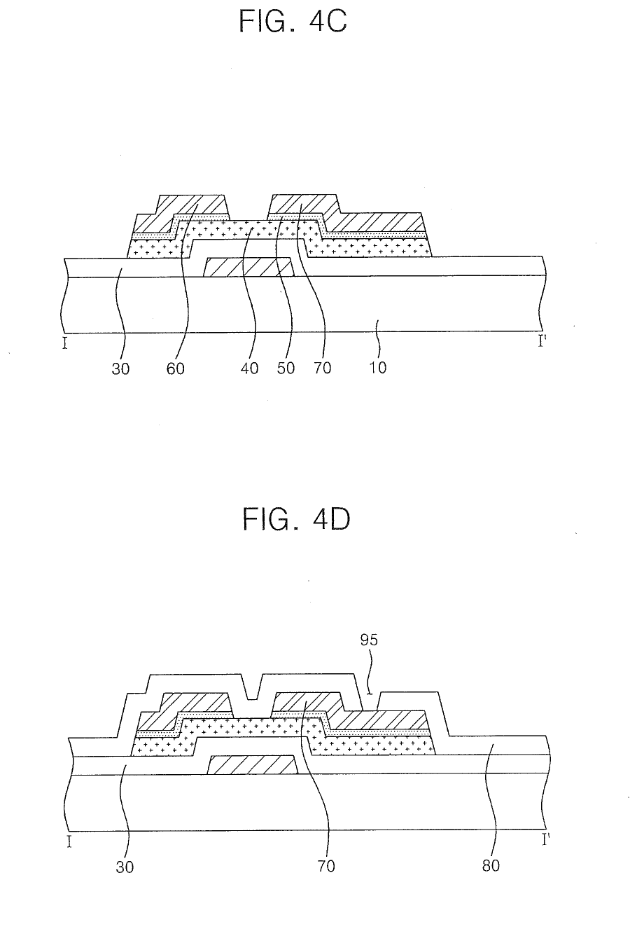

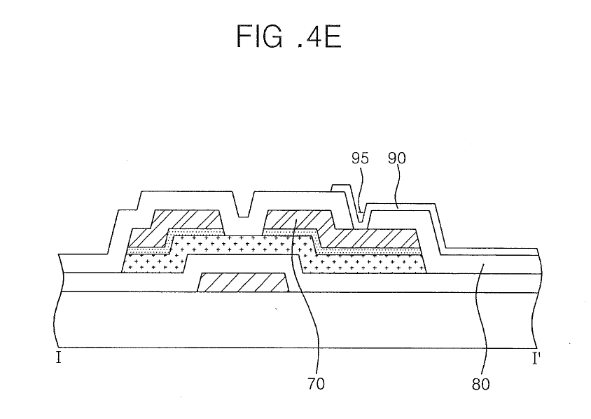

FIGS. 4A to 4E are cross-sectional views showing a second exemplary embodiment of a method of manufacturing an exemplary TFT substrate by each mask process of four masks in accordance with the present invention.

FIG. 4A is a cross-sectional view showing the second exemplary embodiment of a first mask process in a method of manufacturing the exemplary TFT substrate in accordance with the present invention. The first mask process forms a first conductive pattern group on the substrate 10 using a first mask. The first conductive pattern group includes a gate line 21 (as shown in FIG. 1) and a gate electrode 20.

More specifically, the gate metal layer (not shown) is formed on the substrate 10 by a deposition method such as a sputtering. The gate metal layer may be formed of a single layer of a metal such as aluminum (Al), chromium (Cr), copper (Cu), and molybdenum (Mo), etc. or their alloy, or a multiple layer of their combination. Then, the gate metal layer is patterned by a photolithography process and an etching process using the first mask to form the first conductive pattern group including the gate line 21 and the gate electrode 20.

FIGS. 4B and 4C are cross-sectional views showing the second exemplary embodiment of a second mask process in the method of manufacturing the exemplary TFT substrate in accordance with the present invention. The second mask process forms a gate insulating layer 30, a semiconductor layer 40, an ohmic contact layer 50, a data line 61, a source electrode 60, and a drain electrode 70 on the substrate 10, including the first conductive pattern group already formed thereon, using a second mask.

More specifically, as shown in FIG. 4B, the gate insulating layer 30, an a-Si layer 140, an oxide semiconductor layer 150, and a data metal layer 160 are sequentially deposited on the substrate 10, including the first conductive pattern group already formed thereon. For example, the gate insulating layer 30 and the a-Si layer 150 are formed by a PECVD method. The oxide semiconductor layer 150 and the data metal layer 160 are formed by a sputtering method. The gate insulating layer 30 is formed of an insulating material such as silicon oxide (SiOₓ), silicon nitride (SiNₓ), etc. The oxide semiconductor layer 150 is formed of the same material as previously described with respect to the first exemplary embodiment. The data metal layer 160 may be formed of a single layer of a metal material such as aluminum (Al), chromium (Cr), copper (Cu), and molybdenum (Mo), etc. or a double layer or more deposited by the materials.

A photoresist is deposited on the data metal layer 160, and then the photoresist is exposed and developed by a photolithography process using a slit mask to form a photoresist pattern.

Then, a blocking area of the slit mask is positioned at an area where the semiconductor layer 40, the ohmic contact layer 50, and the data pattern are to be formed to block ultraviolet rays, thereby remaining a photoresist pattern after development. A slit area of the slit mask is positioned at an area where a channel of the TFT 100 is formed to diffract ultraviolet rays, thereby removing the photoresist after development.

The exposed portions of the data pattern and the ohmic contact layer 50 located thereunder are all removed by a wet etching process, as shown in FIG. 4C. Since the data metal layer and the oxide semiconductor layer are formed within the same chamber by a sputtering method, they are simultaneously patterned by a wet etching in an etching process. An etching process of the ohmic contact layer 50 is omitted and the same number of masks as in the BCE method is used. The etch stopper (“ES”) method has an advantage of thinly forming an active layer, that is a-Si layer 140, and since a wet etchant of this embodiment has a high etching selectivity, the semiconductor layer 40 may also be thinly formed.

FIG. 4D is a cross-sectional view showing the second exemplary embodiment of a third mask process in the method of manufacturing the exemplary TFT substrate in accordance with the present invention. In FIG. 4D, the third mask process forms a protection layer 80 including a contact hole 95 on the gate insulating layer 30, including the second conductive pattern group already formed thereon, using a third mask.

More specifically, the protection layer 80 is formed on the substrate 10, including the second conductive pattern group already formed thereon, by a PECVD, a spin coating, etc. The contact hole 95 penetrating the protection layer 80 and exposing the drain electrode 70 is formed by a photolithography process and an etching process using the third mask. The protection layer 80 may be formed from an inorganic insulating material, such as the material used for forming the gate insulating layer 30, or an organic insulating material.

FIG. 4E is a cross-sectional view showing the second exemplary embodiment of a fourth mask process in the method of manufacturing the exemplary TFT substrate in accordance with the present invention. In FIG. 4E, the fourth mask process forms a pixel electrode 90 on the protection layer 80 using a fourth mask.

More specifically, the pixel electrode 90 is formed by forming a transparent conductive layer on the protection layer 80 by a method such as a sputtering, etc. and then patterning the transparent conductive layer by a photolithography process and an etching process using the fourth mask. The transparent conductive layer includes a transparent conductive material such as indium tin oxide (ITO), indium zinc oxide (IZO), and tin oxide (TO), etc. The pixel electrode 90 is connected to the drain electrode 70 through the contact hole 95.

As described the above, the TFT substrate and a method of manufacturing the same according to the present invention may simplify a fabrication process and improve its property by forming the ohmic contact layer with the oxide semiconductor. The present invention may obtain both advantages of reducing the number of masks in the BCE method and thinly forming the semiconductor layer in the ES method by forming the ohmic contact layer with the oxide semiconductor.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. A method of manufacturing a thin film transistor substrate, the method comprising:
forming a first conductive pattern group including a gate electrode on a substrate;
forming a gate insulating layer on the first conductive pattern group;
forming a semiconductor layer and an ohmic contact layer on the gate insulating layer by patterning an amorphous silicon layer and an oxide semiconductor layer, respectively;
forming a second conductive pattern group including a source electrode and a drain electrode on the ohmic contact layer by patterning a data metal layer;
forming a protection layer including a contact hole on the second conductive pattern group; and
forming a pixel electrode electrically connected to a portion of the drain electrode through the contact hole on the protection layer.

2. The method of claim 1, wherein, in forming the second conductive pattern group, the data metal layer and the ohmic contact layer are simultaneously patterned by a wet etching.

3. The method of claim 1, wherein forming the ohmic contact layer includes patterning the oxide semiconductor layer formed of zinc oxide.

4. The method of claim 3, wherein forming the ohmic contact layer includes adding any one of elements of group I, group III, group V, and group VII in periodic table to the zinc oxide.

5. The method of claim 1, wherein forming the ohmic contact layer includes patterning the oxide semiconductor layer formed of indium oxide.

6. The method of claim 1, wherein forming the ohmic contact layer includes patterning the oxide semiconductor layer formed of indium tin oxide.

7. The method of claim 1, wherein forming the ohmic contact layer includes patterning the oxide semiconductor layer formed of indium zinc oxide.

8. The method of claim 1, wherein forming the ohmic contact layer includes patterning the oxide semiconductor layer formed of an amorphous oxide semiconductor.

9. A method of manufacturing a thin film transistor substrate, the method comprising:
forming a first conductive pattern group including a gate electrode on a substrate;
sequentially depositing a gate insulating layer, an amorphous silicon layer, an oxide semiconductor layer, and a data metal layer on the first conductive pattern group;
forming a second conductive pattern group including a semiconductor layer, an ohmic contact layer, a source electrode, and a drain electrode by patterning the amorphous silicon layer, the oxide semiconductor layer, and the data metal layer, respectively;
forming a protection layer including a contact hole on the second conductive pattern group; and
forming a pixel electrode electrically connected to a portion of the drain electrode through the contact hole on the protection layer.

10. The method of claim 9, wherein, in forming the second conductive pattern group, the data metal layer and the ohmic contact layer are simultaneously patterned by a wet etching.

11. The method of claim 9, wherein forming the ohmic contact layer includes patterning the oxide semiconductor layer formed of zinc oxide.

12. The method of claim 11, wherein forming the ohmic contact layer includes adding any one of elements of group I, group III, group V, and group VII in periodic table to the zinc oxide.

13. The method of claim 9, wherein forming the ohmic contact layer includes patterning the oxide semiconductor layer formed of indium oxide.

14. The method of claim 9, wherein forming the ohmic contact layer includes patterning the oxide semiconductor layer formed of indium tin oxide.

15. The method of claim 9, wherein forming the ohmic contact layer includes patterning the oxide semiconductor layer formed of indium zinc oxide.

16. The method of claim 9, wherein forming the ohmic contact layer includes patterning the oxide semiconductor layer formed of an amorphous oxide semiconductor.
